(19) United States
(12) Patent Application Publication
(10) Pub. No.: US 2026/0096119 A1
(43) Pub. Date: Apr. 2, 2026

(54) SEMICONDUCTOR DEVICE

(71) Applicant: Mitsubishi Electric Corporation, Tokyo (JP)

(72) Inventors: Kazuya KONISHI, Tokyo (JP); Koji TANAKA, Tokyo (JP); Reona FURUKAWA, Tokyo (JP); Takashi FUJIMOTO, Tokyo (JP); Tetsuya HIGASHI, Tokyo (JP)

(73) Assignee: Mitsubishi Electric Corporation, Tokyo (JP)

(21) Appl. No.: 19/290,299

(22) Filed: Aug. 4, 2025

(30) Foreign Application Priority Data
Sep. 30, 2024 (JP) 2024-169771

(51) Int. Cl. H10D 12/00; H10D 30/66; H10D 62/10; H10D 62/60; H10D 64/23; H10D 64/27

(52) U.S. Cl. CPC H10D 12/481; H10D 30/668; H10D 62/103; H10D 62/60; H10D 64/232; H10D 64/518

(57) ABSTRACT

A semiconductor device according to the present disclosure includes: a semiconductor substrate; a two-stage dummy active trench located in the semiconductor substrate on a side of a front surface thereof, the two-stage dummy active trench including therein a first upper electrode in an upper stage, a first lower electrode in a lower stage, and a first boundary insulating film located between the first upper electrode and the first lower electrode, the first upper electrode being connected to an emitter electrode and covered with a first upper insulating film, the first lower electrode being connected to a gate electrode and covered with a first lower insulating film, wherein a film thickness of the first boundary insulating film is greater than each of a film thickness of the first upper insulating film and a film thickness of the first lower insulating film.

### BACKGROUND

### Technical Field

The present disclosure relates to a semiconductor device in which conduction is controlled by a gate signal.

### Description of the Background Art

In an insulated gate bipolar transistor (IGBT), a change in recovery voltage over time (dV/dt) of a diode at a low current might increase during turn-on operation. High dV/dt causes noise in a product or causes dielectric breakdown of a motor. Measures to increase a gate resistance may be taken to reduce dV/dt, but an increase in gate resistance leads to a new problem of an increase in turn-on loss.

To solve the above-mentioned problem, it is useful to increase a gate capacitance ratio (Cgc/Cge). In a semiconductor device including a two-stage dummy active trench including therein an upper electrode in an upper stage connected to an emitter electrode and a lower electrode in a lower stage connected to a gate electrode, a low gate-emitter capacitance (Cge) can be maintained while a gate-collector capacitance (Cgc) is increased, so that the gate capacitance ratio can be improved to reduce a switching loss (see Japanese Patent Application Laid-Open No. 2015-38954, for example).

Depending on a driving condition or a structure of the semiconductor device, however, a displacement current generated by a variation in potential due to a change in hole density around the trench flows into the lower electrode as a gate potential. This leads to an increase in gate voltage to cause an increase in dV/dt, so that the switching loss sometimes cannot sufficiently be reduced.

### SUMMARY

It is an object of the present disclosure to provide a semiconductor device in which a switching loss can be reduced by suppressing an increase in gate voltage.

A semiconductor device according to the present disclosure includes: a semiconductor substrate; a two-stage dummy active trench located in the semiconductor substrate on a side of a front surface thereof, the two-stage dummy active trench including therein a first upper electrode in an upper stage, a first lower electrode in a lower stage, and a first boundary insulating film located between the first upper electrode and the first lower electrode, the first upper electrode being connected to an emitter electrode and covered with a first upper insulating film, the first lower electrode being connected to a gate electrode and covered with a first lower insulating film, wherein a film thickness of the first boundary insulating film is greater than each of a film thickness of the first upper insulating film and a film thickness of the first lower insulating film.

According to the present disclosure, a switching loss can be reduced by suppressing an increase in gate voltage.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to Embodiment 1;

FIG. 2 is a cross-sectional view of a semiconductor device according to Modification 1 of Embodiment 1;

FIG. 3 is a cross-sectional view of a semiconductor device according to Modification 2 of Embodiment 1;

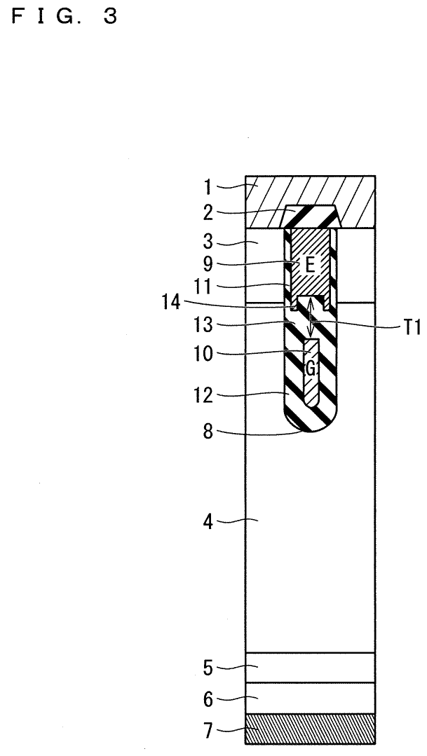

FIG. 4 is a cross-sectional view of a semiconductor device according to Modification 3 of Embodiment 1;

FIG. 5 is a cross-sectional view of a semiconductor device according to Modification 4 of Embodiment 1;

FIG. 6 is a cross-sectional view of a semiconductor device according to Modification 4 of Embodiment 1;

FIG. 7 is a cross-sectional view of a semiconductor device according to Modification 5 of Embodiment 1;

FIG. 8 is a cross-sectional view of a semiconductor device according to Modification 6 of Embodiment 1;

FIG. 9 is a cross-sectional view of a semiconductor device according to Modification 7 of Embodiment 1;

FIG. 10 is a cross-sectional view of a semiconductor device according to Modification 8 of Embodiment 1;

FIG. 11 is a cross-sectional view of a semiconductor device according to Modification 9 of Embodiment 1;

FIG. 12 is a cross-sectional view of a semiconductor device according to Modification 10 of Embodiment 1;

FIG. 13 is a cross-sectional view of a semiconductor device according to Modification 10 of Embodiment 1;

FIG. 14 is a cross-sectional view of a semiconductor device according to Modification 11 of Embodiment 1;

FIG. 15 is a cross-sectional view of a semiconductor device according to Modification 12 of Embodiment 1;

FIG. 16 is a cross-sectional view of a semiconductor device according to Modification 12 of Embodiment 1;

FIG. 17 is a cross-sectional view of a semiconductor device according to Modification 13 of Embodiment 1; and

FIG. 18 is a cross-sectional view of a semiconductor device according to Modification 14 of Embodiment 1.

### DESCRIPTION OF THE PREFERRED EMBODIMENTS

### <Embodiment 1>

A semiconductor device according to an embodiment will be described below with reference to the drawings. The semiconductor device is an IGBT. The same or corresponding components bear the same reference signs, and repeated description is sometimes omitted. In description made below, N and P indicate conductivity types of a semiconductor. These conductivity types may be reversed.

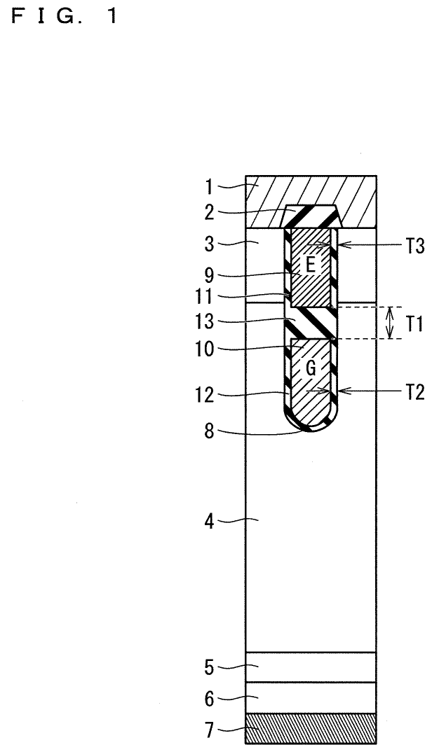

FIG. 1 is a cross-sectional view of a semiconductor device according to Embodiment 1. In FIG. 1, a semiconductor substrate is in a range from a base layer 3 to a collector layer 6. In FIG. 1, an upper end of the base layer 3 is referred to as a front surface of the semiconductor substrate, and a lower end of the collector layer 6 is referred to as a back surface of the semiconductor substrate. The front surface and the back surface face each other.

As illustrated in FIG. 1, the P-type base layer 3 is provided on a side of the front surface of an N-type drift layer 4.

The semiconductor substrate includes a two-stage dummy active trench 8 extending through the base layer 3 to the drift layer 4. The two-stage dummy active trench 8 is located in the semiconductor substrate on a side of the front surface thereof and includes therein a first upper electrode 9 in an upper stage connected to an emitter electrode 1 and a first lower electrode 10 in a lower stage connected to a gate electrode (not illustrated).

The two-stage dummy active trench 8 also includes a first upper insulating film 11 provided to cover a side wall of the first upper electrode 9, a first lower insulating film 12 provided to cover a side wall of the first lower electrode 10, and a first boundary insulating film 13 provided between the first upper electrode 9 and the first lower electrode 10. The first upper electrode 9 and the first lower electrode 10 are electrically separated from each other via the first boundary insulating film 13. A film thickness T1 of the first boundary insulating film 13 is greater than each of a film thickness T3 of the first upper insulating film 11 and a film thickness T2 of the first lower insulating film 12. The film thickness T1 varies in a transverse direction (width direction of the two-stage dummy active trench 8), so that the film thickness T1 in the present disclosure is a film thickness at the center in the transverse direction of the first boundary insulating film 13.

An interlayer insulating film 2 is provided over the two-stage dummy active trench 8. The emitter electrode 1 is provided over the base layer 3 and the interlayer insulating film 2.

On a side of the back surface of the drift layer 4, an N-type buffer layer 5 having a higher N-type impurity concentration than the drift layer 4 is provided. The P-type collector layer 6 is provided on a side of the back surface of the buffer layer 5. A collector electrode 7 is provided on a side of the back surface of the collector layer 6.

The influence of a displacement current is proportional to a length (size in a depth direction) of the first lower electrode 10 as an entry path for the displacement current. Specifically, the displacement current is more likely to flow into the first lower electrode 10 when the first lower electrode 10 has a greater length. On the other hand, a gate capacitance is inversely proportional to a film thickness of an insulating film. Specifically, the gate capacitance decreases with increasing film thickness of the insulating film. A gate-emitter capacitance (Cge) depends on the film thickness of the first boundary insulating film 13, and a gate-collector capacitance (Cgc) having the influence on dV/dt depends on the film thickness of the first lower insulating film 12.

According to Embodiment 1, the first boundary insulating film 13 has a greater film thickness than the first lower insulating film 12, so that a gate capacitance ratio (Cgc/Cge) can be increased, and the first lower electrode 10 as a gate potential into which the displacement current flows can be smaller. A switching loss can thus be reduced by suppressing an increase in gate voltage.

The displacement current generated by a variation in potential by holes has a large influence especially in the IGBT, which is a bipolar device using holes as carriers. According to Embodiment 1, a synergistic effect from the IGBT and the above-mentioned configuration can be obtained to produce a large effect of reducing the displacement current.

### <Modification 1>

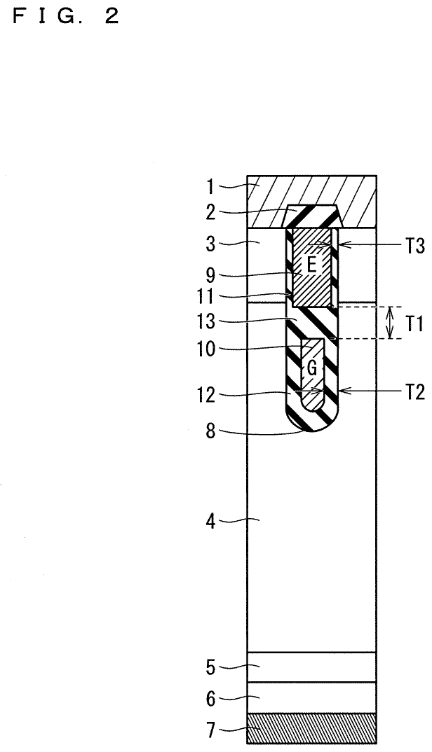

FIG. 2 is a cross-sectional view of a semiconductor device according to Modification 1 of Embodiment 1. As illustrated in FIG. 2, in the semiconductor device according to Modification 1, the film thickness T2 of the first lower insulating film 12 is greater than the film thickness T3 of the first upper insulating film 11.

The displacement current is inversely proportional to the film thickness of the first lower insulating film 12 as an entry path for the displacement current. Specifically, the displacement current decreases with increasing film thickness of the first lower insulating film 12. According to Modification 1, the film thickness T2 of the first lower insulating film 12 is greater than the film thickness T3 of the first upper insulating film 11, so that the displacement current can be reduced, and the increase in gate voltage can be suppressed.

The gate-emitter capacitance (Cge) is proportional to the area of a portion in which the first upper electrode 9 and the first lower electrode 10 face each other. Specifically, the gate-emitter capacitance (Cge) increases with increasing facing area. The facing area herein refers to the area of a portion in which a lower end (a surface on a side of the back surface) of the first upper electrode 9 and an upper end (a surface on a side of the front surface) of the first lower electrode 10 face each other. According to Modification 1, the film thickness T2 of the first lower insulating film 12 is greater than the film thickness T3 of the first upper insulating film 11, so that the area of the portion in which the first upper electrode 9 and the first lower electrode 10 face each other decreases, and thus the gate-emitter capacitance (Cge) can be reduced. The switching loss can thus be reduced while a high gate capacitance ratio (Cgc/Cge) is maintained.

### <Modification 2>

In a semiconductor device according to Modification 2, the film thickness T1 of the first boundary insulating film 13 is equal to or greater than 1.5 times each of the film thickness T3 of the first upper insulating film 11 and the film thickness T2 of the first lower insulating film 12. The semiconductor device according to Modification 2 is similar to the semiconductor device according to Embodiment 1 (see FIG. 1).

The film thickness of the insulating film varies due to the influence of a process of forming the insulating film. Especially the film thickness T1 of the first boundary insulating film 13 varies greatly due to the influence of a shape of the first lower electrode 10 underlying the first boundary insulating film 13 and a shape of the first upper electrode 9 above the first boundary insulating film 13 and is sometimes locally smaller than each of the film thickness T2 of the first lower insulating film 12 and the film thickness T3 of the first upper insulating film 11. Even in a case where there is such a variation, the film thickness T1 of the first boundary insulating film 13 is required to be equal to or greater than 1.5 times each of the film thickness T3 of the first upper insulating film 11 and the film thickness T2 of the first lower insulating film 12 to satisfy a relationship “T1>T2 and T1>T3”. With such a configuration, the switching loss can be reduced by suppressing the increase in gate voltage while a high gate capacitance ratio (Cgc/Cge) is maintained.

According to findings of the inventors, the film thickness T1 of the first boundary insulating film 13 is sometimes reduced by 30% due to the influence of the shape of the first lower electrode 10 underlying the first boundary insulating film 13 and the shape of the first upper electrode 9 above the first boundary insulating film 13. When the film thickness T1 of the first boundary insulating film 13 is equal to or greater than 1.5 times each of the film thickness T3 of the first upper insulating film 11 and the film thickness T2 of the first lower insulating film 12, even if the film thickness T1 is reduced by 30% due to the variation, the film thickness T1 is 1.05 times each of the film thickness T2 and the film thickness T3, and the relationship “T1>T2 and T1>T3” can be satisfied. The switching loss can thus be reduced by suppressing the increase in gate voltage while a high gate capacitance ratio (Cgc/Cge) is maintained.

The film thickness T1 of the first boundary insulating film 13 may desirably be equal to or greater than twice each of the film thickness T3 of the first upper insulating film 11 and the film thickness T2 of the first lower insulating film 12. With such a film thickness, even if the film thickness T1 is reduced by 30% due to the variation, the film thickness T1 is 1.4 times each of the film thickness T2 and the film thickness T3. Thus, compared with a case of an equivalent film thickness, the gate capacitance ratio (Cgc/Cge) can be increased, so that the increase in gate voltage is suppressed, and, further, the switching loss can be reduced.

Even with a configuration in which the first upper electrode 9 includes, on each of left and right sides at a lower end thereof, a prong 14 protruding toward the back surface, a greater film thickness T1 of the first boundary insulating film 13 can be maintained, so that the switching loss can be reduced by suppressing the increase in gate voltage while a high gate capacitance ratio (Cgc/Cge) is maintained.

### <modification 3>

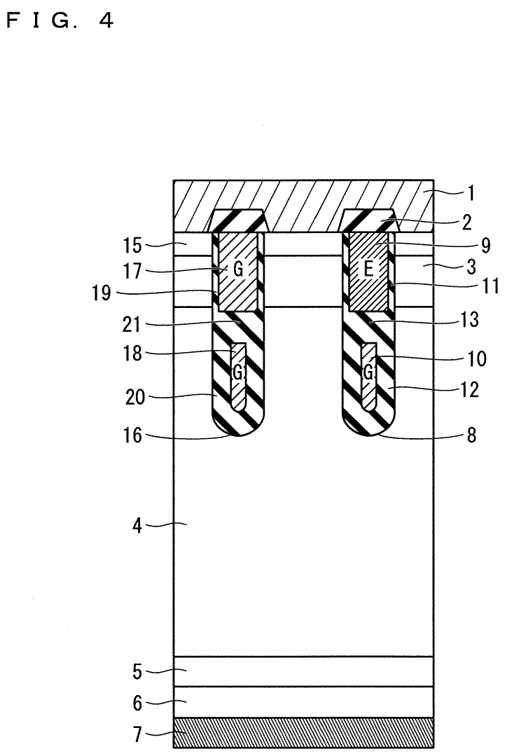

FIG. 4 is a cross-sectional view of a semiconductor device according to Modification 3 of Embodiment 1. As illustrated in FIG. 4, the semiconductor device according to Modification 3 further includes an N-type source layer 15 provided on a side of the front surface of the base layer 3 and a two-stage active trench 16 extending through the source layer 15 and the base layer 3 to the drift layer 4.

The two-stage active trench 16 is located in the semiconductor substrate on the side of the front surface thereof and includes therein a second upper electrode 17 in an upper stage connected to the gate electrode and a second lower electrode 18 in a lower stage connected to the gate electrode.

The two-stage active trench 16 also includes a second upper insulating film 19 provided to cover a side wall of the second upper electrode 17, a second lower insulating film 20 provided to cover a side wall of the second lower electrode 18, and a second boundary insulating film 21 provided between the second upper electrode 17 and the second lower electrode 18. The second upper electrode 17 and the second lower electrode 18 are electrically separated from each other via the second boundary insulating film 21.

According to Modification 3, the two-stage active trench 16 including the second upper electrode 17 as the gate potential and the source layer 15 are included, so that a channel can be formed in the base layer 3 to enable on operation of the semiconductor device.

Especially the second upper electrode 17 and the second lower electrode 18 are subject to the influence of the displacement current as they are gate potentials. The displacement current can thus effectively be reduced by increasing the film thickness of the second boundary insulating film 21.

### <Modification 4>

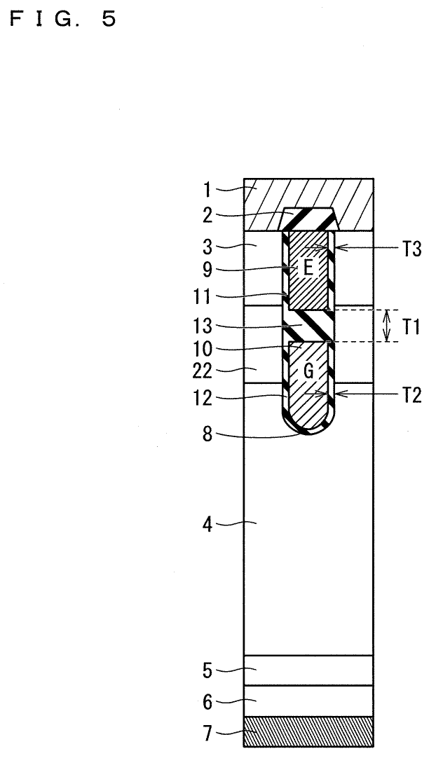

FIG. 5 is a cross-sectional view of a semiconductor device according to Modification 4 of Embodiment 1. As illustrated in FIG. 5, the semiconductor device according to Modification 4 further includes a carrier storage layer 22. The carrier storage layer 22 is provided on a side of the back surface of the base layer 3 (on a side of the front surface of the drift layer 4).

According to Modification 4, the carrier storage layer 22 is included to increase a quantity of stored holes to thereby increase the displacement current. With such a configuration, a synergistic effect from the carrier storage layer 22 and Embodiment 1 can be obtained to especially produce a large effect of reducing the displacement current.

The first boundary insulating film 13 and the carrier storage layer 22 may desirably be located adjacent to each other in the transverse direction. The influence of the displacement current due to densification of holes in the carrier storage layer 22 can thereby be reduced by the first boundary insulating film 13.

An entire region of the first boundary insulating film 13 and the carrier storage layer 22 may more desirably be located adjacent to each other in the transverse direction. The displacement current can thereby further be reduced.

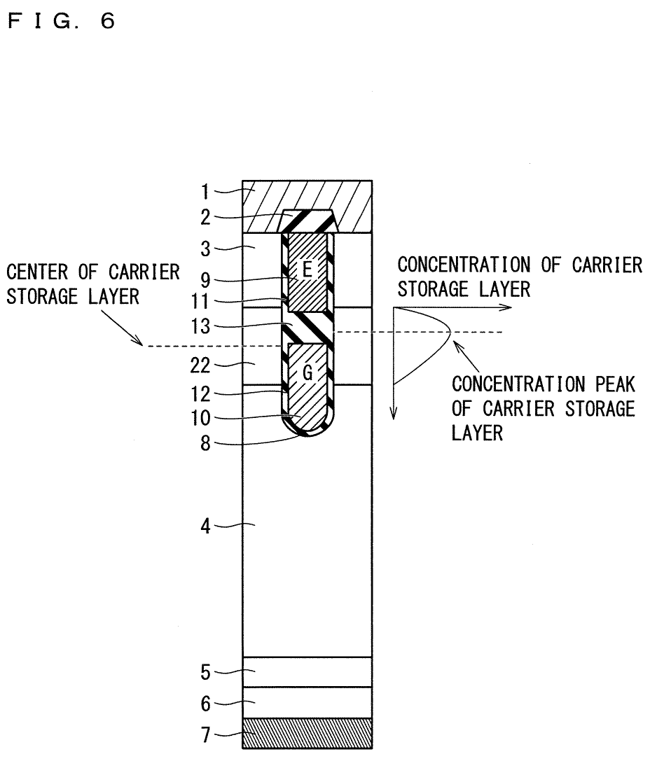

The first boundary insulating film 13 and a concentration peak of the carrier storage layer 22 may more desirably be located adjacent to each other in the transverse direction as illustrated in FIG. 6. The film thickness of the first boundary insulating film 13 is thus increased with respect to a portion of the carrier storage layer 22 having a concentration peak subject to the influence of the displacement current due to densification of holes, so that the influence of the displacement current can be reduced.

As illustrated in FIG. 6, the concentration peak of the carrier storage layer 22 may be located closer to the front surface than the center (center in the depth direction) of the carrier storage layer 22 is. With such a positional relationship, a high concentration portion of the carrier storage layer 22 in which an electric field is likely to increase can be spaced apart from a bottom of the two-stage dummy active trench 8 where an electric field is likely to be concentrated, so that a breakdown voltage can be improved.

The concentration peak of the carrier storage layer 22 may be located closer to the back surface than the center (center in the depth direction) of the carrier storage layer 22 is. With such a positional relationship, holes can be stored mainly in a portion closer to the back surface than the center of the carrier storage layer 22 is, so that a quantity of stored holes on a side of the front surface can be reduced. A region in which the displacement current is generated can thus be smaller, so that the influence of the displacement current can be reduced.

The carrier storage layer 22 according to Modification 4 is applicable to Embodiment 1 and the other modifications.

### <Modification 5>

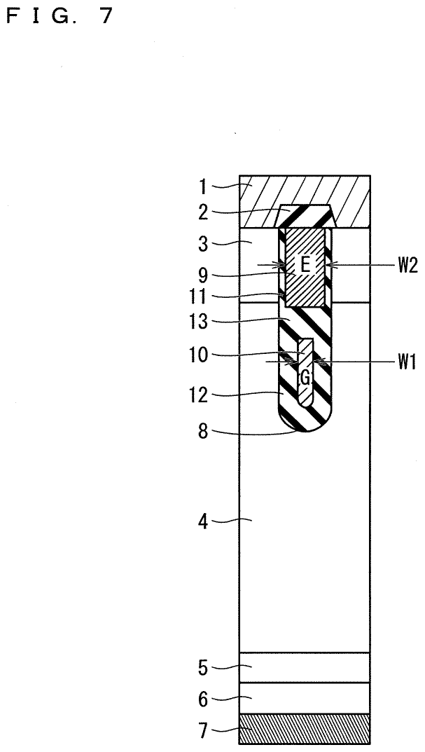

FIG. 7 is a cross-sectional view of a semiconductor device according to Modification 5 of Embodiment 1. As illustrated in FIG. 7, in the semiconductor device according to Modification 5, a width W1 of the first lower electrode 10 is smaller than a width W2 of the first upper electrode 9. The width W1 and the width W2 are herein sizes in the transverse direction (width direction of the two-stage dummy active trench 8).

The displacement current is inversely proportional to the film thickness of the first lower insulating film 12 as the entry path for the displacement current. According to Modification 5, the width W1 of the first lower electrode 10 is smaller than the width W2 of the first upper electrode 9, so that the first lower insulating film 12 can have a greater film thickness. The displacement current can thus be reduced, so that the switching loss can be reduced by suppressing the increase in gate voltage.

### <Modification 6>

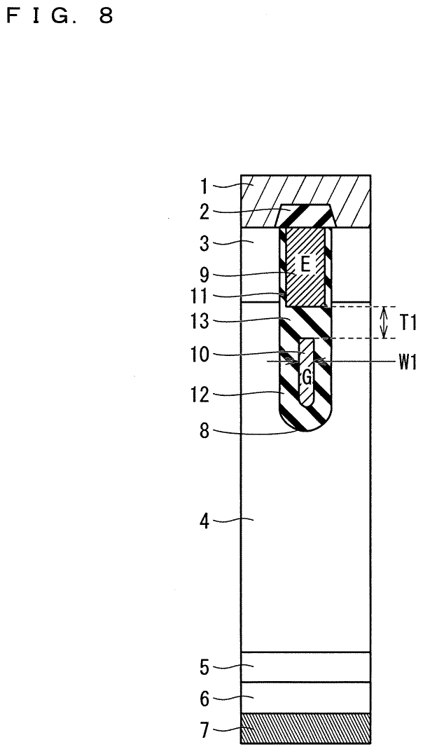

FIG. 8 is a cross-sectional view of a semiconductor device according to Modification 6 of Embodiment 1. As illustrated in FIG. 8, in the semiconductor device according to Modification 6, the film thickness T1 of the first boundary insulating film 13 is greater than the width W1 of the first lower electrode 10.

According to Modification 6, the film thickness T1 of the first boundary insulating film 13 is greater than the width W1 of the first lower electrode 10, so that the first lower electrode 10 into which the displacement current flows can be smaller, and the increase in gate voltage can be suppressed.

The gate-emitter capacitance (Cge) in the first boundary insulating film 13 is proportional to the area of the portion in which the first upper electrode 9 and the first lower electrode 10 face each other and is inversely proportional to the film thickness T1 of the first boundary insulating film 13. The gate-collector capacitance (Cgc) is inversely proportional to the film thickness of the first lower insulating film 12. The width W1 of the first lower electrode 10 as the gate potential is thus smaller than the film thickness T1 of the first boundary insulating film 13, so that reduction in gate-collector capacitance (Cgc) can be reduced while the gate-emitter capacitance (Cge) is further reduced, and thus the high gate capacitance ratio (Cgc/Cge) can be maintained, and the switching loss can be reduced.

### <Modification 7>

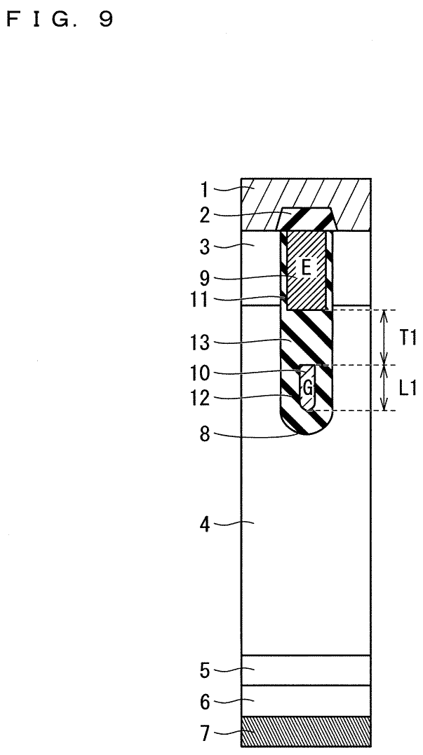

FIG. 9 is a cross-sectional view of a semiconductor device according to Modification 7 of Embodiment 1. As illustrated in FIG. 9, in the semiconductor device according to Modification 7, a length L1 of the first lower electrode 10 is smaller than the film thickness T1 of the first boundary insulating film 13.

A greater film thickness of the first boundary insulating film 13 without a change in length of the first lower electrode 10 leads to a greater depth of the two-stage dummy active trench 8, so that an effective film thickness of the drift layer 4 is reduced to reduce the breakdown voltage. According to Modification 7, the length L1 of the first lower electrode 10 is smaller than the film thickness T1 of the first boundary insulating film 13, so that the displacement current can be reduced while the breakdown voltage is maintained without a change in depth of the two-stage dummy active trench 8, and the increase in gate voltage can be suppressed.

### <Modification 8>

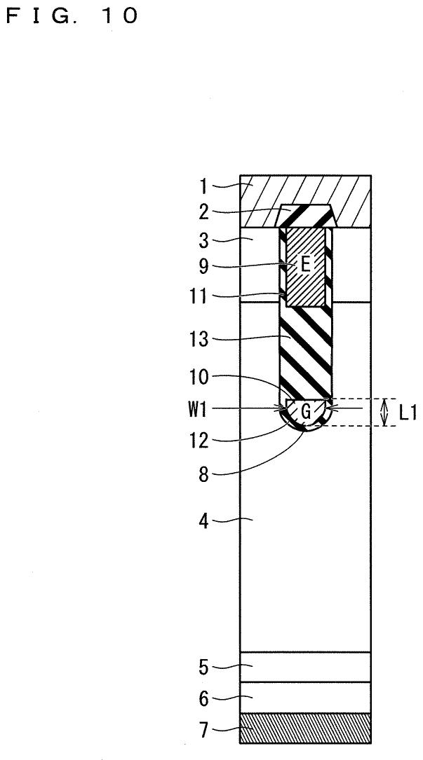

FIG. 10 is a cross-sectional view of a semiconductor device according to Modification 8 of Embodiment 1. As illustrated in FIG. 10, in the semiconductor device according to Modification 8, the width W1 of the first lower electrode 10 is greater than the length L1 of the first lower electrode 10.

According to Modification 8, the width W1 of the first lower electrode 10 is greater than the length L1 of the first lower electrode 10, so that the displacement current can be reduced, and the increase in gate voltage can be reduced.

Furthermore, the film thickness of the first boundary insulating film 13 can be increased while the gate-collector capacitance (Cgc) is increased by reducing the film thickness of the first lower insulating film 12, so that the gate-emitter capacitance (Cge) can be reduced. Thus, the high gate capacitance ratio (Cgc/Cge) can be maintained, and the switching loss can be reduced.

### <Modification 9>

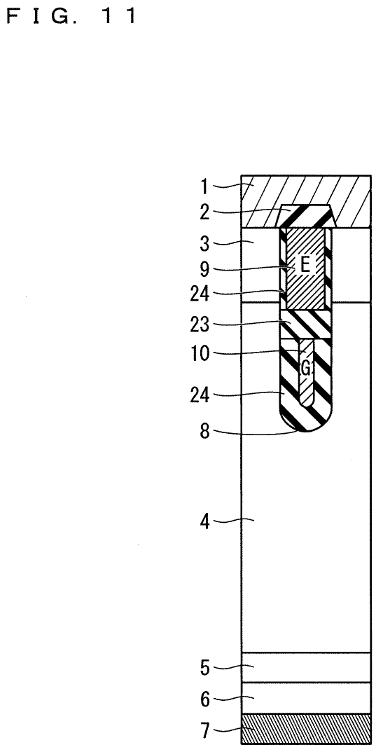

FIG. 11 is a cross-sectional view of a semiconductor device according to Modification 9 of Embodiment 1. As illustrated in FIG. 11, in the semiconductor device according to Modification 9, the first boundary insulating film 13 has a higher impurity concentration than each of the first upper insulating film 11 and the first lower insulating film 12. Specifically, a chemical vapor deposition (CVD) film 23 as the first boundary insulating film 13 has a higher impurity concentration than a thermal oxide film 24 as each of the first upper insulating film 11 and the first lower insulating film 12. The first boundary insulating film 13 may have a higher impurity concentration than one of the first upper insulating film 11 and the first lower insulating film 12.

CVD generally enables formation of an insulating film having a greater film thickness with good productivity compared with thermal oxidation. The thermal oxide film 24 is superior to the CVD film in terms of electrical characteristics. The CVD film 23 has a higher impurity concentration than the thermal oxide film. Examples of the CVD film include high temperature oxide (HTO), tetra eth oxy silane (TEOS), and borophospho tetra ethyl ortho silicate (BPTEOS).

According to Modification 9, the first boundary insulating film 13 has a higher impurity concentration than each of the first upper insulating film 11 and the first lower insulating film 12. Specifically, the first boundary insulating film 13 is the CVD film 23, and the first upper insulating film 11 and the first lower insulating film 12 are each the thermal oxide film 24. The first boundary insulating film 13 having a greater film thickness can thereby be formed with good productivity. The first upper insulating film 11 and the first lower insulating film 12 relating to electrical characteristics at an interface of the trench are each the thermal oxide film 24, so that electrical characteristics of a gate can be improved.

### <Modification 10>

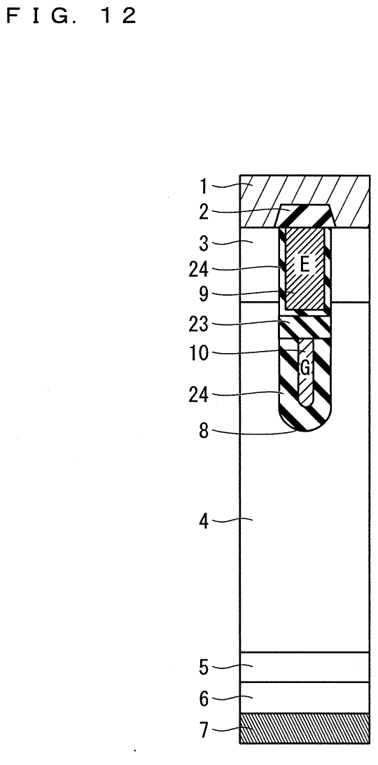

FIG. 12 is a cross-sectional view of a semiconductor device according to Modification 10 of Embodiment 1. As illustrated in FIG. 12, in the semiconductor device according to Modification 10, the first boundary insulating film 13 includes two layers including a layer having a high impurity concentration (first layer) and a layer having a low impurity concentration (second layer). Specifically, the layer having the high impurity concentration is the CVD film 23, and the layer having the low impurity concentration is the thermal oxide film 24.

According to Modification 10, after the CVD film 23 as a portion of the first boundary insulating film 13 is formed by CVD, the thermal oxide film 24 forming a portion of the first boundary insulating film and the first upper insulating film 11 is formed in a step of forming the thermal oxide film. As a result, the first boundary insulating film 13 includes the two layers including the CVD film 23 and the thermal oxide film 24. The first boundary insulating film 13 can thus have a greater film thickness, and the gate-emitter capacitance (Cge) can be reduced.

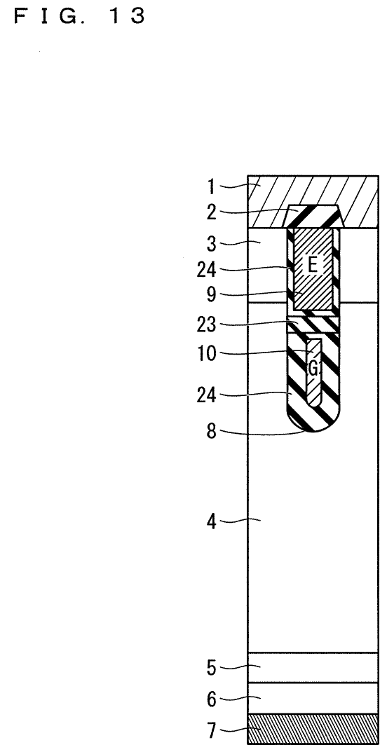

As illustrated in FIG. 13, the first boundary insulating film 13 may include three layers including the CVD film 23 and two thermal oxide films 24 sandwiching the CVD film 23. A thermal oxide film 24 on a side of the back surface of the CVD film 23 is formed by thermal oxidation in a step before a step of forming the CVD film 23. The first boundary insulating film 13 can thus have a greater film thickness, and the gate-emitter capacitance (Cge) can be reduced.

### <Modification 11>

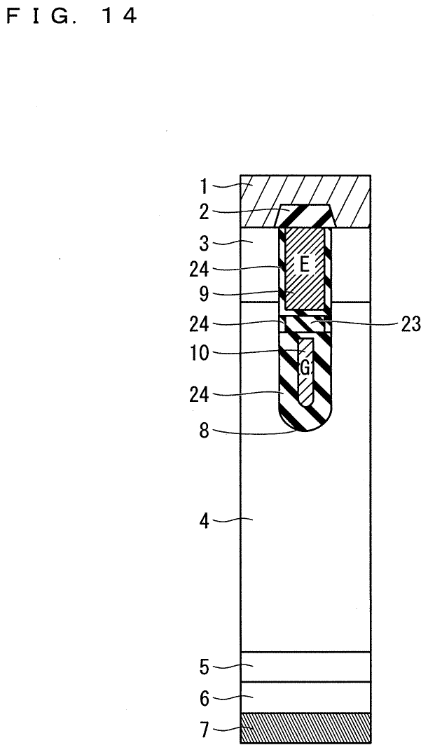

FIG. 14 is a cross-sectional view of a semiconductor device according to Modification 11 of Embodiment 1. As illustrated in FIG. 14, first portions of the first boundary insulating film 13 being in contact with the drift layer 4 (a semiconductor layer) included in the semiconductor substrate each have a lower impurity concentration than a second portion other than the first portions of the first boundary insulating film 13. Specifically, the first portions of the first boundary insulating film 13 are thermal oxide films 24, and the second portion of the first boundary insulating film 13 is the CVD film 23.

According to Modification 11, the portions of the first boundary insulating film 13 being in contact with the semiconductor layer are the thermal oxide films 24, so that electrical characteristics can be improved.

### <Modification 12>

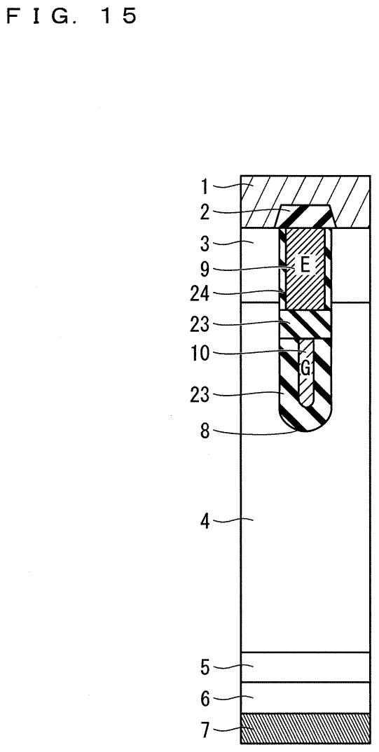

FIG. 15 is a cross-sectional view of a semiconductor device according to Modification 12 of Embodiment 1. As illustrated in FIG. 15, in the semiconductor device according to Modification 12, the first boundary insulating film 13 and the first lower insulating film 12 each have a higher impurity concentration than the first upper insulating film 11. Specifically, the first boundary insulating film 13 and the first lower insulating film 12 are CVD films 23, and the first upper insulating film 11 is the thermal oxide film 24.

According to Modification 12, the first boundary insulating film 13 and the first lower insulating film 12 each having a greater film thickness can be formed with good productivity by CVD, so that a manufacturing cost can be reduced.

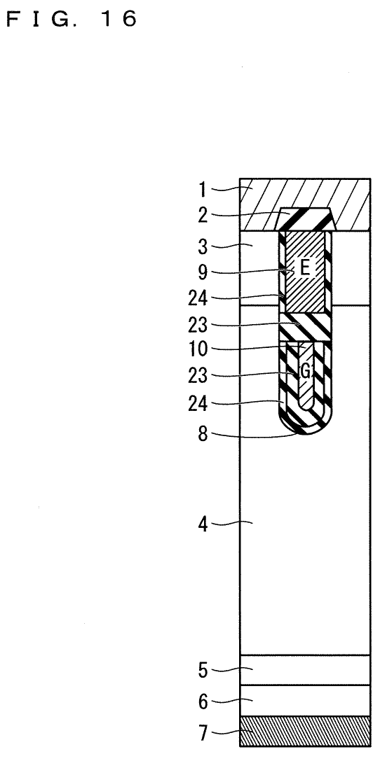

As illustrated in FIG. 16, the first lower insulating film 12 may include two layers including the thermal oxide film 24 and the CVD film 23. Although not illustrated, the first upper insulating film 11 may include two layers including the thermal oxide film 24 and the CVD film 23.

### <Modification 13>

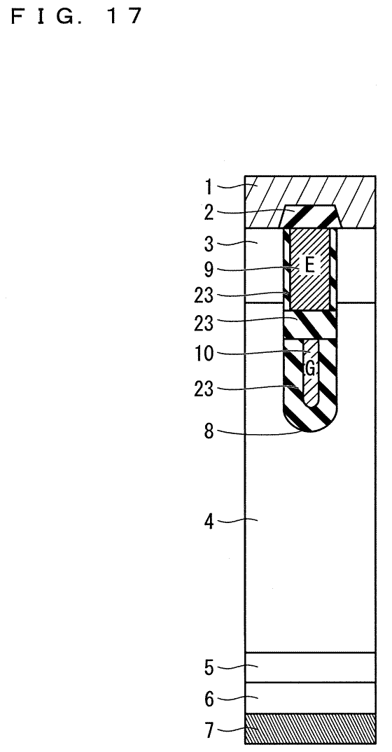

FIG. 17 is a cross-sectional view of a semiconductor device according to Modification 13 of Embodiment 1. As illustrated in FIG. 17, in the semiconductor device according to Modification 13, the first upper insulating film 11, the first lower insulating film 12, and the first boundary insulating film 13 are each the CVD film 23.

According to Modification 13, the first upper insulating film 11, the first lower insulating film 12, and the first boundary insulating film 13 can be formed with good productivity by CVD, so that the manufacturing cost can be reduced.

### <Modification 14>

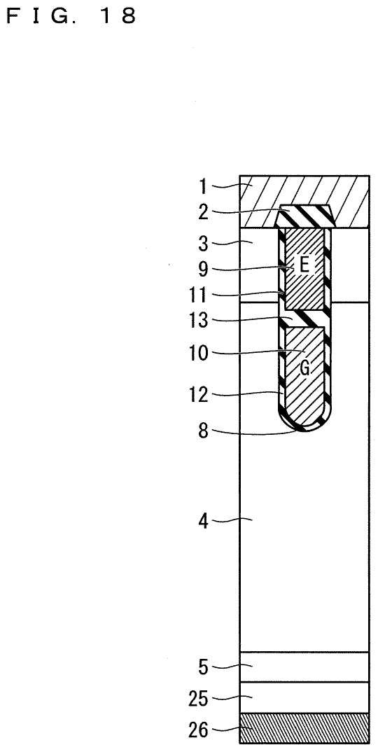

FIG. 18 is a cross-sectional view of a semiconductor device according to Modification 14 of Embodiment 1. As illustrated in FIG. 18, the semiconductor device according to Modification 14 is a metal oxide semiconductor field effect transistor (MOSFET) including a drain layer 25 located in the semiconductor substrate on a side of the back surface and a drain electrode 26 provided on a side of the back surface of the drain layer 25. The other configuration is similar to that in Embodiment 1 (see FIG. 1).

The MOSFET is a unipolar device in which holes do not contribute to on operation, so that the influence of the displacement current due to the holes is small. On the other hand, the MOSFET enables faster switching due to the absence of the holes, so that dV/dt increases. The displacement current is determined by the product of dV/dt and a gate-drain capacitance (Cgd) and thus increases in the MOSFET during high-frequency operation.

According to Modification 14, the two-stage dummy active trench 8 including the first boundary insulating film 13 having a greater film thickness is included, so that the switching loss can be reduced while the increase in gate voltage is suppressed.

### <Modification 15>

In a semiconductor device according to Modification 15, the semiconductor substrate includes a wide bandgap semiconductor. Examples of the wide bandgap semiconductor include SiC (silicon carbide), GaN (gallium nitride), and Ga₂O₃ (gallium oxide).

A similar effect to that obtained in Embodiment 1 can be obtained even with a configuration in which the semiconductor substrate includes the wide bandgap semiconductor as in Modification 15. In particular, the wide bandgap semiconductor enables fast switching compared with Si, so that the displacement current increases due to an increase in dV/dt. The semiconductor device according to the present disclosure includes the two-stage dummy active trench 8 including the first boundary insulating film 13 having a greater film thickness, so that the switching loss can be reduced while the increase in gate voltage is suppressed in the wide bandgap semiconductor in which the displacement current increases.

The embodiment can be modified or omitted as appropriate within the scope of the present disclosure.

### APPENDICES

Various aspects of the present disclosure will collectively be described below as appendices.

### Appendix 1

A semiconductor device comprising:
a semiconductor substrate;
a two-stage dummy active trench located in the semiconductor substrate on a side of a front surface thereof, the two-stage dummy active trench including therein a first upper electrode in an upper stage, a first lower electrode in a lower stage, and a first boundary insulating film located between the first upper electrode and the first lower electrode, the first upper electrode being connected to an emitter electrode and covered with a first upper insulating film, the first lower electrode being connected to a gate electrode and covered with a first lower insulating film, wherein
a film thickness of the first boundary insulating film is greater than each of a film thickness of the first upper insulating film and a film thickness of the first lower insulating film.

### Appendix 2

The semiconductor device according to Appendix 1, wherein
the film thickness of the first lower insulating film is greater than the film thickness of the first upper insulating film.

### Appendix 3

The semiconductor device according to Appendix 1 or 2, wherein
the film thickness of the first boundary insulating film is equal to or greater than 1.5 times each of the film thickness of the first upper insulating film and the film thickness of the first lower insulating film.

### Appendix 4

The semiconductor device according to any one of Appendices 1 to 3, further comprising
a two-stage active trench located in the semiconductor substrate on the side of the front surface thereof, the two-stage active trench including therein a second upper electrode in an upper stage and a second lower electrode in a lower stage, the second upper electrode being connected to the gate electrode, the second lower electrode being connected to the gate electrode.

### Appendix 5

The semiconductor device according to any one of Appendices 1 to 4, wherein
the semiconductor device is an insulated gate bipolar transistor (IGBT) including a collector layer located in the semiconductor substrate on a side of a back surface thereof.

### Appendix 6

The semiconductor device according to any one of Appendices 1 to 5, further comprising
a carrier storage layer located in the semiconductor substrate.

### Appendix 7

The semiconductor device according to any one of Appendices 1 to 6, wherein
a width of the first lower electrode is smaller than a width of the first upper electrode.

### Appendix 8

The semiconductor device according to any one of Appendices 1 to 7, wherein
the film thickness of the first boundary insulating film is greater than a width of the first lower electrode.

### Appendix 9

The semiconductor device according to any one of Appendices 1 to 8, wherein
a length of the first lower electrode is smaller than the film thickness of the first boundary insulating film.

### Appendix 10

The semiconductor device according to any one of Appendices 1 to 9, wherein
a width of the first lower electrode is greater than a length of the first lower electrode.

### Appendix 11

The semiconductor device according to any one of Appendices 1 to 10, wherein
the first boundary insulating film has a higher impurity concentration than at least one of the first upper insulating film and the first lower insulating film.

### Appendix 12

The semiconductor device according to any one of Appendices 1 to 11, wherein
the first boundary insulating film includes two or more layers including a first layer and a second layer having a lower impurity concentration than the first layer.

Appendix 13

The semiconductor device according to any one of Appendices 1 to 12, wherein
a first portion of the first boundary insulating film being in contact with a semiconductor layer included in the semiconductor substrate has a lower impurity concentration than a second portion other than the first portion of the first boundary insulating film.

### Appendix 14

The semiconductor device according to any one of Appendices 1 to 13, wherein
the first boundary insulating film and the first lower insulating film each have a higher impurity concentration than the first upper insulating film.

### Appendix 15

The semiconductor device according to any one of Appendices 1 to 10, wherein
the first upper insulating film, the first lower insulating film, and the first boundary insulating film are each a chemical vapor deposition (CVD) film.

### Appendix 16

The semiconductor device according to any one of Appendices 1 to 15, wherein
the semiconductor device is a metal oxide semiconductor field effect transistor (MOSFET) including a drain layer located in the semiconductor substrate on a side of a back surface thereof.

### Appendix 17

The semiconductor device according to any one of Appendices 1 to 16, wherein
the semiconductor substrate includes a wide bandgap semiconductor.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
a two-stage dummy active trench located in the semiconductor substrate on a side of a front surface thereof, the two-stage dummy active trench including therein a first upper electrode in an upper stage, a first lower electrode in a lower stage, and a first boundary insulating film located between the first upper electrode and the first lower electrode, the first upper electrode being connected to an emitter electrode and covered with a first upper insulating film, the first lower electrode being connected to a gate electrode and covered with a first lower insulating film, wherein
a film thickness of the first boundary insulating film is greater than each of a film thickness of the first upper insulating film and a film thickness of the first lower insulating film.

2. The semiconductor device according to claim 1, wherein
the film thickness of the first lower insulating film is greater than the film thickness of the first upper insulating film.

3. The semiconductor device according to claim 1, wherein
the film thickness of the first boundary insulating film is equal to or greater than 1.5 times each of the film thickness of the first upper insulating film and the film thickness of the first lower insulating film.

4. The semiconductor device according to claim 1, further comprising
a two-stage active trench located in the semiconductor substrate on the side of the front surface thereof, the two-stage active trench including therein a second upper electrode in an upper stage and a second lower electrode in a lower stage, the second upper electrode being connected to the gate electrode, the second lower electrode being connected to the gate electrode.

5. The semiconductor device according to claim 1, wherein
the semiconductor device is an insulated gate bipolar transistor (IGBT) including a collector layer located in the semiconductor substrate on a side of a back surface thereof.

6. The semiconductor device according to claim 1, further comprising
a carrier storage layer located in the semiconductor substrate.

7. The semiconductor device according to claim 1, wherein
a width of the first lower electrode is smaller than a width of the first upper electrode.

8. The semiconductor device according to claim 1, wherein
the film thickness of the first boundary insulating film is greater than a width of the first lower electrode.

9. The semiconductor device according to claim 1, wherein
a length of the first lower electrode is smaller than the film thickness of the first boundary insulating film.

10. The semiconductor device according to claim 1, wherein
a width of the first lower electrode is greater than a length of the first lower electrode.

11. The semiconductor device according to claim 1, wherein
the first boundary insulating film has a higher impurity concentration than at least one of the first upper insulating film and the first lower insulating film.

12. The semiconductor device according to claim 1, wherein
the first boundary insulating film includes two or more layers including a first layer and a second layer having a lower impurity concentration than the first layer.

13. The semiconductor device according to claim 1, wherein
a first portion of the first boundary insulating film being in contact with a semiconductor layer included in the semiconductor substrate has a lower impurity concentration than a second portion other than the first portion of the first boundary insulating film.

14. The semiconductor device according to claim 1, wherein
the first boundary insulating film and the first lower insulating film each have a higher impurity concentration than the first upper insulating film.

15. The semiconductor device according to claim 1, wherein
the first upper insulating film, the first lower insulating film, and the first boundary insulating film are each a chemical vapor deposition (CVD) film.

16. The semiconductor device according to claim 1, wherein
the semiconductor device is a metal oxide semiconductor field effect transistor (MOSFET) including a drain layer located in the semiconductor substrate on a side of a back surface thereof.

17. The semiconductor device according to claim 1, wherein
the semiconductor substrate includes a wide bandgap semiconductor.
